(19) United States
(12) Patent Application Publication
(10) Pub. No.: US 2026/0066857 A1
(43) Pub. Date: Mar. 5, 2026

(54) METHODS AND APPARATUS TO REGULATE AN AMPLIFIER

(71) Applicant: Texas Instruments Incorporated, Dallas, TX (US)

(72) Inventors: Sumit Dubey, Bangalore (IN); Aditya Sundar, Bangalore (IN); Aditya Agrawal, Bangalore (IN); Laxmi Vivek Tripurari, Bangalore (IN); Anand Subramanian, Bangalore (IN); Anand Kannan, Bangalore (IN)

(21) Appl. No.: 18/820,003

(22) Filed: Aug. 29, 2024

(51) Int. Cl. H03F 3/185

(52) U.S. Cl. CPC H03F 3/1855; H03F 2200/264; H03F 2203/45174

(57) ABSTRACT

Methods, apparatus, systems, and articles of manufacture are described to regulate an amplifier. An example apparatus includes an integrator, an input terminal of the integrator coupled to a terminal of a first resistor circuitry and an output terminal of the integrator coupled to a capacitor; an output stage, an input terminal of the output stage coupled to the output terminal of the integrator; second resistor circuitry, a first terminal of the second resistor circuitry coupled to the output terminal of the output stage, a second terminal of the second resistor circuitry coupled to the terminal of the first resistor circuitry and the input terminal of the integrator; and third resistor circuitry, a first terminal coupled to the terminal of the first resistor circuitry, the second terminal of the second resistor circuitry, and the input terminal of the integrator.

### TECHNICAL FIELD

This description relates generally to amplifiers, and, more particularly, to methods and apparatus to regulate an amplifier.

### BACKGROUND

A computing device (e.g., a laptop, a tablet, a cell phone, headphones, speakers, etc.) may include one or more speakers to output audio generated by a processing unit or application implemented by the computing device or a connected computing device. Some computing devices utilize class-D amplifiers. A class-D amplifier is a switching amplifier that switches back and forth between supply voltages to amplify an audio signal before applying the audio signal to a speaker for output. Class D-amplifiers are efficient, small, inexpensive, and utilize less power than other amplifiers.

### SUMMARY

For regulating an amplifier, an example apparatus includes first resistor circuitry having a terminal; a capacitor having a first terminal and a second terminal; an integrator having an input terminal and an output terminal, the input terminal of the integrator coupled to the terminal of the first resistor circuitry and the first terminal of the capacitor, and the output terminal of the integrator coupled to the second terminal of the capacitor; an output stage having an input terminal and an output terminal, the input terminal of the output stage coupled to the output terminal of the integrator; second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator; and third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal. Other examples are described.

For regulating an amplifier, an example apparatus includes a capacitor having a first terminal and a second terminal; resistor circuitry having a first terminal and a second terminal; an integrator having an input terminal and an output terminal, the input terminal of the integrator coupled to the first terminal of the capacitor and the output terminal of the integrator coupled to the second terminal of the capacitor; an output stage having an input terminal and an output terminal, the input terminal of the output stage coupled to the output terminal of the integrator, the output terminal of the output stage coupled to the first terminal of the resistor circuitry; a variable resistor having a first terminal, a second terminal, and a control terminal, the first terminal of the variable resistor coupled to the second terminal of the resistor circuitry and the input terminal of the integrator, the second terminal of the variable resistor coupled to a common terminal; control circuitry including a first terminal and a second terminal; an analog-to-digital converter having an input terminal and an output terminal; and regulation circuitry having a first input terminal, a second input terminal, a third input terminal, and an output terminal, the first input terminal of the regulation circuitry coupled to the output terminal of the analog-to-digital converter, the second input terminal of the regulation circuitry coupled to the first terminal of the control circuitry, and the third input terminal of the regulation circuitry coupled to the second terminal of the control circuitry, the output terminal of the regulation circuitry coupled to the control terminal of the variable resistor. Other examples are described.

For regulating an amplifier, an example system includes a processing unit configured to output an audio signal; a digital-to-analog converter configured to convert the audio signal into an analog audio signal; amplifier circuitry to convert the analog audio signal into a pulse width modulated audio signal, the amplifier circuitry including: a capacitor having a first terminal and a second terminal; first resistor circuitry having a terminal; an integrator having an input terminal and an output terminal, the input terminal of the integrator coupled to the terminal of the first resistor circuitry and the first terminal of the capacitor, and the output terminal of the integrator coupled to the second terminal of the capacitor; an output stage having an input terminal and an output terminal, the input terminal of the output stage coupled to the output terminal of the integrator; second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator; and third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal; and a speaker configured to output audio, the speaker having an input terminal, the input terminal of the speaker coupled to the output terminal of the output stage. Other examples are described.

### BRIEF DESCRIPTION OF THE DRAWINGS

FIG. 1 is an example computing device including a speaker to output audio in conjunction with examples described herein.

FIG. 2 is a block diagram of an example implementation of the conversion circuitry of FIG. 1.

FIG. 3 is a block diagram of an alternative example implementation of the conversion circuitry of FIG. 1.

FIG. 4 is an example implementation of the resistor configuration of the conversion circuitries of FIGS. 2-3.

FIG. 5 is an example implementation of an output stage of the conversion circuities of FIGS. 2-3.

FIG. 6 illustrates an example graph illustrating noise savings corresponding to examples described herein for different supply voltages.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines or boundaries may be idealized. In reality, the boundaries or lines may be unobservable, blended or irregular.

Computing devices may include or be connected to speakers (e.g., via a wired or wireless connection) to output audio. Such computing devices may include an amplifier to amplify the audio signal to drive the speaker to output audio corresponding to the audio signal. Class-D audio amplifiers are generally used to drive speakers where high efficiency is required at high signal output powers. An example audio signal path includes an input that obtains a digital audio signal (e.g., from a processor), digital to analog converter circuitry to convert the input digital audio signal to an analog signal, a class-D amplifier to convert and amplify the analog signal to a high voltage pulse width modulated (PWM) signal that drives a speaker.

Like all speakers, it is desirable for speaker to have low idle channel noise (e.g., low output noise when the speaker is idle). Noise at the output of a class-D amplifier may be caused by at least one of a current to voltage amplifier that drives the class-D input, an integrator of a loop filter, a feedback resistor, and an input resistor. Also, in some architectures, a common mode setting amplifier is used to regulate a virtual net common mode, which also adds noise.

Some audio amplifier systems use dynamic range enhancement (DRE) to minimize the noise at the Class-D output by varying analog and digital gain dynamically based on input amplitude level to reduce analog noise at low levels of audio. For example, DRE includes monitoring digital input data and automatically adjusting two complimentary gains within the audio signal path. In situations where the digital input is has a relatively low value, the input digital gain increases and the output analog gain decreases by an equivalent amount (e.g., the higher the input digital gain the lower the output analog gain). In situations where the audio input level is high, no or minimal gain is added to the digital input and no or minimal gain exchange is made to the analog output. DRE improves signal-to-noise ratio of low-level signals without increasing the overall channel gain.

PVDD is a voltage that is applied to supplied to the output stage (or power stage) and corresponds to the output voltage of the output stage. For example, the output stage can output a high voltage (e.g., a PVDD voltage from a supply terminal) or a low voltage (e.g., 0 V from a ground terminal of the output stage). The PVDD voltage at the output stage of the audio signal path is high, leading to a high switching loss from transistor in the output stage, which is proportional to the PVDD voltage. In systems that include a low frequency electromagnetic interference inductor capacitor filter, the higher the duty cycle of the signal output by the output stage, the higher the switching loss. Also, a higher duty cycle results in a higher current ripple caused by an output filter (e.g., electromagnetic interference (EMI) inductor capacitor (LC) filter). Accordingly, most designers or systems can utilize a common technique of hybrid modulation. Hybrid modulation includes applying low duty cycles with variable PVDD voltage to reduce switching loss and current ripples.

However, as PVDD rises, the DC voltage at the input of the integrator in the class-D amplifier rises, and the AC ripple at the input of the integrator also rises. If the DC voltage or AC ripple is too high, the integrator, which can only operate in situations where the DC voltage is below a threshold, will not work properly. Accordingly, the resistors coupled to the integrator need to be adjusted to limit the gain of the class D amplifier. However, limiting the gain results in attenuation of noise from any proceeding component along the audio signal path.

Also, because class D amplifiers may utilize fully differential input audio signals, there may be a common mode DC current flowing through the resistors of the class-D amplifiers. Any mismatch between the input resistors or the feedback resistors in the class-D amplifiers results in an increase offset at the output of the class-D amplifier, resulting in an audible click or popping noise or other audible degradations. A common mode rejection ratio (CMRR) of an amplifier corresponds to the ability to suppress the common mode signal from being converted to a differential signal. The higher the mismatch, the lower the CMRR, thereby corresponding to higher the degradation of the audio. Accordingly, the more the resistors mismatch, the more the performance is degraded.

Examples described herein include a class-D amplifier with circuitry to at least one of reduce noise and minimize or eliminate the CMRR issues (e.g., when the CMRR is too low) caused by resistor mismatch. For example, the class-D amplifiers described herein dynamically regulate the DC input voltages to the integrator to ensure that the common mode voltage between the inputs is 0 V or close to 0 V, thereby reducing, or otherwise eliminating, CMRR issues. Also, the class-D amplifiers described herein couple the input voltages of the integrator to ground via a resistor such as variable resistor. The variable resistor creates a high voltage drop to draw common mode current toward ground to help the input resistor to lower an input voltage even for a high PVDD, thereby allowing lower gain to mitigate the input noise. Accordingly, the resistor reduces input noise without limiting the gain of the class D amplifier.

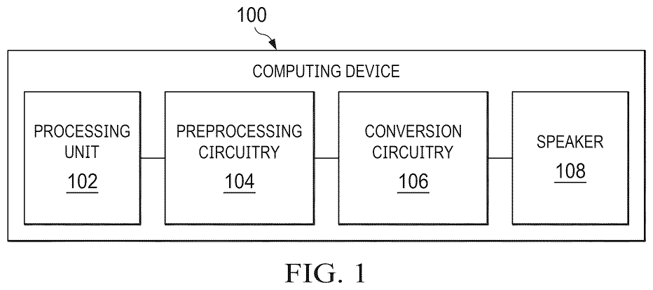

FIG. 1 illustrates an example computing device 100. The computing device 100 of FIG. 1 includes an example processing unit 102, example preprocessing circuitry 104, example conversion circuitry 106, and an example speaker 108. The computing device 100 of FIG. 1 may be a computer, a laptop, a television, a cell phone, a tablet, a monitor, a receiver, a set-top-box, or any other type of computing device. Although the example computing device 100 includes all of the components, one or more of the components may be implemented in one or more external devices. For example, the processing unit 102 and the preprocessing circuitry 104 may be implemented in a first device (e.g., a cell phone, laptop, a vehicle, etc.) and the conversion circuitry 106 and the speaker 108 may be implemented in a second device (e.g., headphones, wireless speakers, etc.). Also, one or more of the components of the computing device 100 may be removed or combined. Also, additional components may be added to the computing device 100.

The processing unit 102 of FIG. 1 performs one or more functions based on applications or instructions. The processing unit 102 may be a central processing unit, a graphical processing unit, a digital signal processor, a microprocessor, a hard drive, a controller, a microcontroller, or any other processing unit. The processing unit 102 may execute or instantiate instructions or applications. The instructions or applications may generate or output an audio signal to be played via the example speaker 108. Accordingly, the processing unit 102 can output an audio signal to the speaker 108 via the preprocessing circuitry 104 and the conversion circuitry 106. The processing unit 102 is coupled to the preprocessing circuitry 104.

The preprocessing circuitry 104 of FIG. 1 adjusts the audio signal from the processing unit 102 to optimize (e.g., improve quality, add effects, change properties, etc.) the audio signal. In some examples, the preprocessing circuitry 104 includes a sound card. The preprocessing circuitry 104 obtains the audio signal from the processing unit 102, adjusts the audio signal, and passes the adjusted audio signal to the conversion circuitry 106. The preprocessing circuitry 104 is coupled to the processing unit 102 and the conversion circuitry 106.

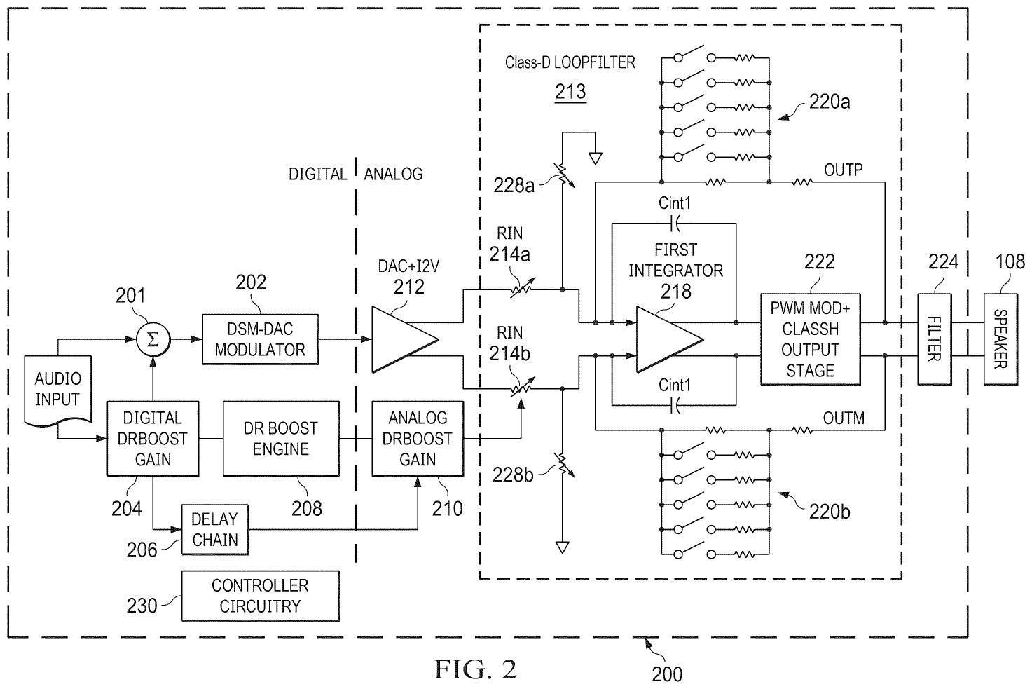

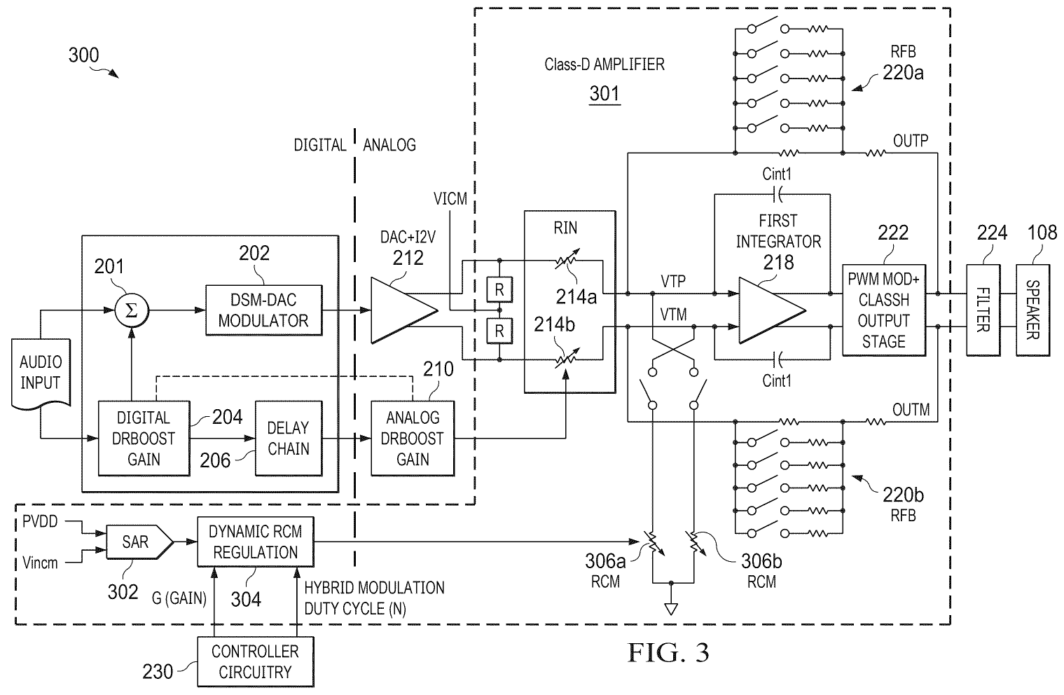

The conversion circuitry 106 of FIG. 1 converts a low digital audio signal from the preprocessing circuitry 104 into an analog signal and converts the analog signal to a high power PWM signal that can be used by the speaker 108 to output audio. The conversion circuitry 106 includes a class-D amplifier that at least one of reduces noise or mitigates CMRR issues using variable resistors that are coupled to a common terminal (e.g., ground) and the input terminals of an integrator of the class D-amplifier. The conversion circuitry 106 is coupled to the processing circuitry 104 and the speaker 108. The conversion circuitry 106 is further described below in conjunction with FIGS. 2 and 3.

The speaker 108 of FIG. 1 outputs audio based on an obtained audio signal from the conversion circuitry 106. For example, if the audio signal corresponds to music or speech, the speaker 108 will convert the audio signal into the music or speech and output the music or speech to a user.

FIG. 2 includes an example implementation of conversion circuitry 200 that may be used to implement the conversion circuitry 106 of FIG. 1. The conversion circuitry 200 of FIG. 2 includes example summation circuitry 201, an example modulator 202, example digital boost gain circuitry 204, an example delay chain 206, an example boost engine 208, example analog boost gain circuitry 210, an example digital to analog (DAC) converter 212, an example class D amplifier 213 (including example variable input resistor circuitry 214a, 214b, an example integrator 218, example variable feedback resistor circuitry 220a, 220b, example PWM and output stage circuitry 222, and example resistors 228a, 228b), an example filter 224, and example controller circuitry 230. FIG. 2 further includes the speaker 108 of FIG. 1. Although FIG. 2 illustrates a fully differential structure, FIG. 2 can be implemented in a single ended system.

The summation circuitry 201 of FIG. 2 includes a first input terminal, a second input terminal, and an output termina. The first input terminal of the summation circuitry 201 is coupled to the preprocessing circuitry 104 of FIG. 1. The second input terminal of the summation circuitry 201 is coupled to an output terminal of the digital boost gain circuitry 206. The output terminal of the summation circuitry 201 is coupled to an input terminal of the modulator 202. The summation circuitry 201 obtains an audio signal (e.g., output from the processing unit 102) and adds the audio signal by a gain generated by the digital boost gain circuitry 206. The summation circuitry 201 outputs the amplified audio signal to the modulator 202.

The modulator 202 of FIG. 2 includes an input terminal and an output terminal. The input terminal of the modulator 202 is coupled to the output terminal of the summation circuitry 201. The output terminal of the modulator 202 is coupled to an input terminal of the DAC 212. The modulator 202 converts the input audio signal as a digital voltage to an audio signal that is an analog current signal that corresponds to the analog voltage signal.

The digital boost gain circuitry 204 of FIG. 2 includes an input terminal and three output terminals. The input terminal of the digital boost gain circuitry 204 is coupled to the preprocessing circuitry 104 of FIG. 1. The first output terminal of the digital boost gain circuitry 204 is coupled to the second input of the summation circuitry 201. The second output terminal of the digital boost gain circuitry 204 is coupled to a first input of the delay chain circuitry 206. The third output terminal of the digital boost gain circuitry 204 is coupled to a first input of the boost engine circuitry 208. In situations where the digital input audio signal is low, the boost gain circuitry 204 increases the gain of the digital audio input signal and outputs the increased gain signal to the summation circuitry 201, the boost engine 208, and the delay chain circuitry 206. In situations where the digital input audio signal is high or at a maximum, the boost gain circuitry 204 does not apply a gain to the input audio signal.

The delay chain circuitry 206 includes an input terminal and an output terminal. The input terminal of the delay chain circuitry 206 is coupled to the digital boost gain circuitry 204 and the output terminal of the delay chain circuitry 206 is coupled to the analog boost gain circuitry 210. The delay chain circuitry 206 compensates for a change in gain for the digital input.

The boost engine 208 of FIG. 2 includes an input terminal and an output terminal. The first terminal of the boost engine 208 is coupled to the third output of the digital boost gain circuitry 204. The output terminal of the boost engine 208 is coupled to the analog boost gain circuitry 210.

The analog boost gain circuitry 210 of FIG. 2 includes a first input terminal, a second input terminal, and an output terminal. The first input terminal of the analog boost gain circuitry 210 is coupled to the boost engine 208. The second input terminal of the analog boost gain circuitry 210 is coupled to the delay chain 206. The output of the analog boost gain circuitry 210 is coupled to a control terminal(s) of one or more of the variable input resistor circuitry 214a, 214b.

As further described below, the variable input resistor circuitry 214a, 214b may include a number of resistors and switches. Control of (e.g., closing and opening) the switches can change the total resistance of the variable input resistor circuitry 214a, 214b. Accordingly, the output of the analog boost gain circuitry 210 can be coupled to the different control terminals of the switches to control the variable resistance of the variable resistor circuitry 214a, 214b based on the signals from the delay chain 206 or the boost engine 208. By controlling the resistance of the input variable resistor circuitry 214a, 214b, the analog boost gain circuitry 210 controls the gain of the class D amplifier 213. The boost gain circuitry 204, delay chain circuitry 206, boost engine 208, and boost gain 210 can dynamically change the resistance of the input variable resistor circuitry 214a, 214b to improve signal-to-noise ratios of low-level signals without increasing overall channel gain. For example, the boost gain circuitry 204, delay chain circuitry 206, boost engine 208, and boost gain 210 monitors the digital input audio signal and automatically adjusts the two complementary gains of the path by controlling the input variable resistor circuitry 214a, 214b. For example, the boost gain circuitry 204, delay chain circuitry 206, boost engine 208, and boost gain 210 adjusts the resistance of the resistors 214a, 214b to reduce signal-to-noise ratio based on the level of the input audio signal.

The digital to analog converter (DAC) 212 of FIG. 2 includes an input terminal, a first differential output terminal, and a second differential output terminal. The input terminal of the DAC 212 is coupled to the DAC modulator 202. The first differential output terminal of the DAC 212 is coupled to the variable input resistor circuitry 214a. The second differential output terminal of the DAC 212 is coupled to the variable input resistor circuitry 214b. The DAC 212 converter an input analog audio current signal into two differential analog voltage signals (e.g., a first analog signal corresponding to the digital audio signal via the first differential output terminal and a second analog signal that is an inverse of the first analog signal via the second differential output terminal).

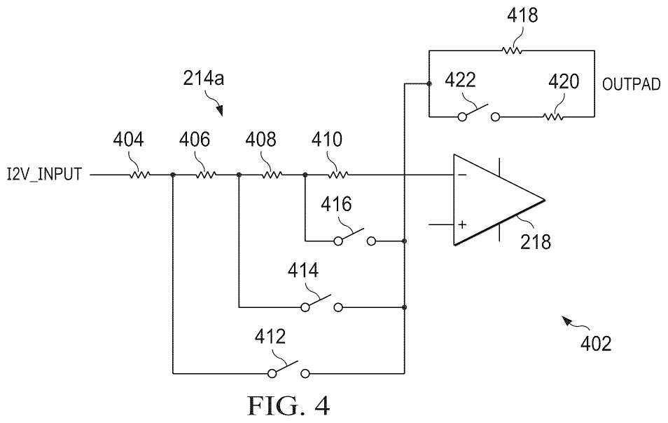

The input variable resistor circuitry 214a, 214b of FIG. 2 each include a first terminal and a second terminal. The first terminal of the input resistor circuitry 214a is coupled to the first differential output terminal of the DAC 212. The first terminal of the input resistor circuitry 214b is coupled to the second differential output terminal of the DAC 212. The second terminal of the variable resistor circuitry 214a is coupled to the variable resistor 228a, the feedback resistors 220a, and the integrator 218. The second terminal of the variable resistor circuitry 214b is coupled to the variable resistor 228b, the feedback resistors 220b, and the integrator 218. The input variable resistor circuitry 214a, 214b includes circuitry that can change resistance based on control signal(s) from the analog boost gain circuitry 210. For example, the input variable resistor circuitry 214a, 214b may include a plurality of switches and resistors. The analog boost gain circuitry 210 can individually control the switches to couple of decouple one or more of the resistors to change the total resistance. As described above, the boost gain circuitry 204, delay chain circuitry 206, boost engine 208, and boost gain 210 can dynamically change the resistance of the input variable resistor circuitry 214a, 214b to improve signal-to-noise ratios of low-level signals without increasing overall channel gain. Example circuitry to implement the variable input resistor circuitry 214a, 214b is further described below in conjunction with FIG. 4.

The integrator 218 of FIG. 2 includes a first differential input, a second differential input, a first differential output and a second differential output. The first differential input of the integrator 218 is coupled to the variable input resistor circuitry 214a, the variable resistor 228a, the variable feedback resistor 220a, and the first differential output of the integrator 218 (e.g., via a first feedback capacitor). The second differential input of the integrator 218 is coupled to the variable input resistor circuitry 214b, the variable resistor 228b, the variable feedback resistor 220b, and the second differential output of the integrator 218 (e.g., via a second feedback capacitor). The first differential output terminal of the integrator 218 is coupled to the first differential input of the integrator 218 (e.g., via the first feedback capacitor) and the output stage 222. The second differential output terminal of the integrator 218 is coupled to the second differential input of the integrator 218 (e.g., via the second feedback capacitor) and the output stage 222. The integrator 218 integrates the output stage differential outputs with the input differential analog audio signals forming a closed loop to remove or reduce errors in the output. The integrator 218 provides the differential output signals that correspond to the integrated output stage differential to the output stage circuitry 222.

The feedback resistor circuitry 220a, 220b of FIG. 2 each include a first terminal and a second terminal. The first terminal of the feedback resistor circuitry 220a is coupled to the output stage 222 and the filter 224. The first terminal of the feedback resistor circuitry 220b is coupled to the output stage 222 and the filter 224. The second terminal of the feedback resistor circuitry 220a is coupled to the input resistor circuitry 214a, the resistor 228a, and the integrator 218. The second terminal of the feedback resistor circuitry 220b is coupled to the input resistor circuitry 214b, the resistor 228b, and the integrator 218. The feedback resistor circuitry 220a, 220b includes a plurality of resistors and a plurality of switches. The switches can be individually enabled or disabled to increase or decrease the resistance of the feedback resistor circuitry 220a, 220b. The total resistance of the feedback resistor circuitry 220a controls the gain of the class D amplifier 213 (e.g., analog channel gain (G)=Rfb/Rin, where Rfb is the total resistance of the feedback resistor circuitry 220a or 220b and Rin is the total resistance of the input resistor circuitry 214a and 214b). The resistance of the feedback resistor circuitry 220a, 220b is selected during testing and is selected for trimming to reduce mismatch in the feedback resistor circuitry 220a, 220b. The resistance is static (e.g., the user or manufacturer can select the resistance, but the resistance does not dynamically change based on feedback information). Although FIG. 2 illustrates the feedback resistor circuitry 220a, 220b as including a particular number of resistors and switches in a particular structure, the feedback resistor circuitry 220a, 220b can be structured in any structure with any number of resistors or switches to provide feedback resistance. For example, an alternative structure of the feedback resistor circuitry 220a is shown in FIG. 4.

The output stage 222 of FIG. 2 includes two input terminals and two output terminals. The first input terminal and the second input terminal of the integrator 218 are coupled to the output stage 222. The first output terminal of the output stage 222 is coupled to the feedback resistor circuitry 220a and the filter 224. The second output terminal of the output stage 222 is coupled to the feedback resistor circuitry 220b and the filter 224. The output stage 222 converts the differential analog signals output by the first integrator 218 into PWM signals that can be used to drive the speaker 108. The output stage 222 may include a comparator that compares the differential outputs of the integrator 218 to high frequency signal(s) (e., one or more triangle waves). The output of the comparator results in one or more series of pulses. The output stage 222 further includes one or more drivers to drive high power switching transistors based on the one or more series of pulses. The output of the high-power switching transistors is one or more pulse width modulated signals that correspond to the input audio signal. The output stage outputs the pulse width modulated signals to the filter 224. An example implementation of the positive path of the output stage 222 is further described below in conjunction with FIG. 4.

The filter 224 of FIG. 2 includes two input terminals and two output terminals. The first input terminal of the filter 224 is coupled to the output stage 222 and the feedback resistor circuitry 220a. The second input terminal of the filter 224 is coupled to the output stage 222 and the feedback resistor circuitry 220b. The first and second output terminals of the filter 224 are coupled to the speaker 108. The filter 224 is a low pass filter that filters out high frequency noise that may be present in the PWM signal output by the output stage 222. The filter 224 may include at least one of a capacitor coupled to ground or an inductor to filter out the high frequency noise.

The resistors 228a, 228b of FIG. 2 each include a first terminal and a second terminal. The first terminal of the resistor 228a is coupled to a common terminal (e.g., ground). The second terminal of the resistor 228a is coupled to the input resistor circuitry 214a, the feedback resistor circuitry 220a and the integrator 218. The first terminal of the resistor 228b is coupled to the input resistor circuitry 214b, the feedback resistor circuitry 220b and the integrator 218. The resistors 228a, 228b are static resistors that aid the input resistors circuitry 214a, 214b in improving the signal to noise ratio. Because the supply voltage applied to the integrator 218 is much lower than the supply voltage at the output stage 222, the resistance of the input resistors 214a, 214b is limited, thereby limiting the gain of the class D amplifier 213. For example, if the resistances of the input resistors 214a, 214b are too high, the input voltage into the integrator 218 can go above the threshold voltage of the integrator 218, thereby causing the integrator 218 to not operate as intended. Accordingly, the resistors 228a, 228b are coupled to ground to aid in the improvement of the signal to noise ratio while allowing allow the input resistors 214a, 214b to be limited for proper operation of the integrator 218.

The example controller circuitry 230 of FIG. 2 controls operation of portions of the conversion circuitry 200. For example, the controller circuitry 230 can use firmware to control the switches 220a, 220b based on the user defined feedback resistance. Also, the controller circuitry 230 can at least one of determine or control the duty cycle of the output stage 222 and the supply voltage of the output stage 222. For example, the controller circuitry 230 can use firmware to dynamically control the duty cycle of the signal output by the output stage 222 to reduce the duty cycle at lower input signal amplitude to reduce switching losses. In some examples, the controller circuitry 230 can adjust the supply voltage at the output stage 222 dynamically based on the audio signal to improve efficiency (e.g., because applying a low supply voltage at low audio levels reduces switching losses). Although the conversion circuitry 200 of FIG. 2 reduces noise by adding resistance at the input of the integrator 218 so that the input resistors 214a, 214b can be limited while still sufficiently reducing noise, the conversion circuitry 200 of FIG. 2 does not minimize or eliminate the CMRR issues caused by resistor mismatch. As further described below, the conversion circuitry 300 of FIG. 3 reduces noise while minimizing CMRR issues caused by resistor mismatch.

FIG. 3 includes an example implementation of conversion circuitry 300 that may be used to implement the conversion circuitry 106 of FIG. 1. The conversion circuitry 300 of FIG. 3 includes the example summation circuitry 201, the example modulator 202, the example digital boost gain circuitry 204, the example delay chain 206, the example analog boost gain circuitry 210, the example digital to analog (DAC) converter 212, the example variable input resistor circuitry 214a, 214b, the example integrator 218, the example variable feedback resistor circuitry 220a, 220b, the example PWM and output stage circuitry 222, the example filter 224, and the example controller circuitry 230 of FIG. 2. The conversion circuitry 300 of FIG. 3 further includes an example class D amplifier 301. The class D amplifier 301 includes an example successive approximation register (SAR) 302, example dynamic resistance regulation circuitry 304, and example variable common mode resistor 306a, 306b. FIG. 3 further includes the speaker 108 of FIG. 1. Although FIG. 3 illustrates a fully differential structure, FIG. 3 can be implemented in a single ended system.

The SAR 302 of FIG. 3 includes two input terminals and an output terminal. The first input terminal of the SAR 302 is coupled to a supply (PVDD) terminal of the power stage 222. The second terminal of the SAR 302 is coupled to a common mode node or terminal (Vincm) between the inputs of the integrator 218. In FIG. 3, the common mode terminal is a terminal that is coupled to the first input terminal of the integrator 218 via a first resistor and coupled to the second input terminal of the integrator 218 via a second resistor. The output terminal of the SAR 302 is coupled to the dynamic common mode resistance regulation circuitry 304. The SAR 302 is an analog-to-digital converter that uses a binary search algorithm to convert an analog signal to a digital representation of the analog signal. Accordingly, the SAR 302 converts the analog PVDD supply voltage from the output stage 222 to a digital value and converts the analog common mode voltage at the input terminal of the integrator 218 to a digital value. In some examples, the SAR 302 may include two SARs (e.g., one for the PVDD voltage and one for the Vincm voltage). The SAR 302 outputs the digital representation of the PVDD voltage and the digital representation of the Vincm voltage to the dynamic common mode resistance regulation circuitry 304. The SAR 302 is a single component that time multiplexes the inputs. However, in some examples, the SAR 302 can be replaced with two SARs (e.g., one to convert the first input and a second one to convert the second input).

The dynamic common mode resistance regulation circuitry 304 of FIG. 3 has three input terminals and an output terminal. The first input terminal of the dynamic common mode resistance regulation circuitry 304 is coupled to the SAR 302. The second input terminal of the dynamic common mode resistance regulation circuitry 304 is coupled to the controller circuitry 230. The third input terminal of the dynamic common mode resistance regulation circuitry 304 is coupled to the controller circuitry 230. The dynamic common mode resistance regulation circuitry 304 controls the resistances of the variable common mode resistors 306a, 306b to adjust the common mode input voltage (e.g., also referred to as a virtual terminal DC voltage) at the virtual terminal common mode node or terminal (VTcm node) to a desired level. As described above, any mismatch between the resistance of the resistor circuitry 214a and 214b or between the resistance of the resistor circuitry 220a, 220b will result in a common mode voltage mismatch (e.g., corresponding to a low common mode rejection ratio), which will increase offset at the output which results in a degradation of the audio. Accordingly, the dynamic common mode resistance regulation circuitry 304 adjusts the resistance of one or more of the resistors 306a, 306b to reduce common mode voltage mismatch corresponding to the input of the integrator 218. For example, the dynamic common mode resistance regulation circuitry 304 can adjust the resistance of one or more of the resistors 306a, 306b based on the supply voltage of the output stage, the common mode input voltage, the gain of the class D amplifier 213, and the duty cycle of the amplifier to ensure that the VTcm voltage at the VTcm node or terminal is equal to the input common mode voltage in DC so that the voltage difference across the input resistor is 0 Volts. Because voltage difference across the input resistor is zero, there will be no CMRR issues. The dynamic common mode resistance regulation circuitry 304 obtains the gain (e.g., including or corresponding to the resistance of the input resistor circuitry 214a, 214b and the feedback resistor circuitry 220a, 220b), and the hybrid modulation duty cycle (N) from the controller circuitry 230, which is stored in memory of the controller circuitry 230. The dynamic common mode resistance regulation circuitry 304 determines the resistance to apply to the resistors 306a, 306b based on the below Equation 1.

$$V {T}_{C M} = ( {Vout}_{c m} ) ( Rin \vert \vert Rcm ) ( Rfb ) + ( Vincm ) ( Rfb \vert \vert Rcm ) / Rin \qquad ( Equation 1 )$$

In the above Equation 1, VTcm is the common mode input voltage (e.g., also referred to as a virtual terminal DC voltage) at the virtual terminal common mode node or terminal (VTcm node or terminal). Voutcm is the common mode output voltage at the speaker 108. Rin is the resistance of the input resistor circuitry 214a, 214b. Rcm is the resistance of the variable resistors 306a, 306b (e.g., which is the variable solved for). Rfb is the resistance of the feedback resistor circuitry 220a, 220b. Vincm is the input common mode voltage at the Vincm node or terminal. The Voutcm can be determined based on a product of the supply voltage of the output stage 222 and the duty cycle (e.g., Voutcm=PVDD*duty_cycle). The dynamic common mode resistance regulation circuitry 304 may be implemented by one or more of software, firmware, or hardware. For example, the dynamic common mode resistance regulation circuitry 304 may be implemented by a look up table that associates one or more PVDD values, Vicm values, gain values, input resistance values, feedback resistance values, or hybrid modulated duty cycles to one or more common mode resistances to apply to the common mode resistors 306a, 306b (e.g., based on the above Equation 1). For example, because Voutcm can be determined based on the supply voltage of the output stage 222 and the duty cycle, and the Vtcm is a function of resistor ratios, the Vincm and Voutcm voltages, the lookup table can correspond to the above Equation 1 to generate an output resistance for the Rem resistors 306a, 306b based on the PVDD, Vincm, gain, and duty cycle. In this manner, the dynamic Rem regulation 304 can generate one or more control signals corresponding to one or more particular resistances to apply to the common mode resistors 306a, 306b by identifying the particular resistances in the lookup table that correspond to the inputs (e.g., one or more of PVDD, Vincm, gain, input resistance, feedback resistance, or duty cycle).

The class D amplifier 301 of FIG. 3 replaces the static common mode resistors 228a, 228b of FIG. 2 with the variable common mode resistors 306a, 306b. The variable resistors 306a, 306b each include a first terminal, a second terminal, and a control terminal. The first terminal of the resistor 306a is coupled to (e.g., via a switch) the first terminal of the integrator 218, the resistor circuitry 214a, 220a, and the first output terminal of the integrator 218 (e.g., via the first feedback capacitor). The second terminal of the resistor 306a is coupled to ground. The control terminal of the resistor 306a is coupled to the dynamic common mode resistance regulation circuitry 304. The first terminal of the resistor 306b is coupled to (e.g., via a switch) the second terminal of the integrator 218, the resistor circuitry 214b, 220b, and the second output terminal of the integrator 218 (e.g., via the second feedback capacitor). The second terminal of the resistor 306b is coupled to ground. The control terminal of the resistor 306b is coupled to the dynamic common mode resistance regulation circuitry 304. The switches are controlled by the controller circuitry 230 to enable or disable the use of the common mode resistors 306a, 306b based on user or manufacturer preferences.

FIG. 4 illustrates an example structure of the input resistor circuitry 214a, 214b of FIG. 2 or 3 and example feedback resistor circuitry 402. The feedback resistor circuitry 402 is an alternative structure of the feedback resistor circuitry 220a of FIG. 2 or 3. FIG. 4 includes example resistors 404, 406, 408, 410, 418, 420 and example switches 412, 414, 416, 422. FIG. 4 further includes the integrator 218 of FIG. 2 or 3.

The resistors 404, 406, 408, 410, 418, 420 and the switches 412, 414, 416, 422 of FIG. 4 each include a first terminal and a second terminal. The first terminal of the resistor 404 is coupled to the first output terminal of the digital to analog converter 212 and the second terminal of the resistor 404 is coupled to the first terminal of the resistor 406 and the first terminal of the switch 412. The first terminal of the resistor 406 is coupled to the second terminal of the resistor 406 and the first terminal of the switch 412 and the second terminal of the resistor 406 is coupled to the first terminal of the resistor 408 and the first terminal of the switch 414. The first terminal of the resistor 408 is coupled to the second terminal of the resistor 406 and the first terminal of the switch 414 and the second terminal of the resistor 408 is coupled to the first terminal of the resistor 410 and the first terminal of the switch 416. The first terminal of the resistor 410 is coupled to the second terminal of the resistor 408 and the first terminal of the switch 416 and the second terminal of the resistor 410 is coupled to the first terminal of the integrator 218, the second terminal of the resistor 418 and the second terminal of the switch 422.

The first terminal of the switch 412 of FIG. 4 is coupled to the resistors 404, 406 and the second terminal of the switch 412 is coupled to the resistors 410, 418, the switch 422, and the first terminal of the integrator 218. The first terminal of the switch 414 is coupled to the resistors 406, 408 and the second terminal of the switch 414 is coupled to the resistors 410, 418, the switch 422, and the first terminal of the integrator 218. The first terminal of the switch 416 is coupled to the resistors 408, 410 and the second terminal of the switch 416 is coupled to the resistors 410, 418, the switch 422, and the first terminal of the integrator 218.

The first terminal of the resistor 418 of FIG. 4 is coupled to an output stage and a filter (e.g., the output stage 222 and the filter 224 of FIG. 2 or 3) and the first terminal of the resistor 420 and the second terminal of the resistor 418 is coupled to the second terminals of the switches 412, 414, 416, 422, the second terminal of the resistor 410, and the first input terminal of the integrator 218. The first terminal of the resistor 420 of FIG. 4 is coupled to an output stage and a filter (e.g., the output stage 222 and the filter 224 of FIG. 2 or 3) and the first terminal of the resistor 418 and the second terminal of the resistor 420 is coupled to the first terminal of the switch 422. The first terminal of the switch 422 is coupled to the second terminal of the resistor 420. The second terminal of the switch 422 is coupled to the second terminals of the switches 412, 414, 416, the second terminal of the resistor 418, the second terminal of the resistor 410, and the first input terminal of the integrator 218.

Also, the switches 412, 414, 416, 422 each also include a control terminal. The control terminals of the switches 412, 414, 416 are coupled to the analog boost gain circuitry 210 and the control terminal of the switch 422 is coupled to the controller circuitry 230.

As described above, the analog boost gain circuitry 210 can control the resistance of the variable resistor 214a based on the level of the input audio signal. In the example of FIG. 4, the analog boost gain circuitry 210 can output one or more control signals to the one or more switches 412, 414, 416 to connect or disconnect one or more of the resistors 406, 408, 410 to the input of the integrator 218, thereby adjusting the input resistor circuitry resistance. Likewise, after a feedback resistance has been determined (e.g., based on user or manufacturer preferences), the controller circuitry 230 applies a control signal to the switch 422 to couple or decouple the resistor 420 from the input of the integrator 218, thereby adjusting the feedback resistor circuitry resistance. Although FIG. 4 illustrates a particular way to implement the input resistor circuitry 214a and the feedback resistor circuitry 402, there may be other ways to implement the input resistor circuitry 214a, 402 using a different number of resistors or switches or using other resistor adjustment techniques.

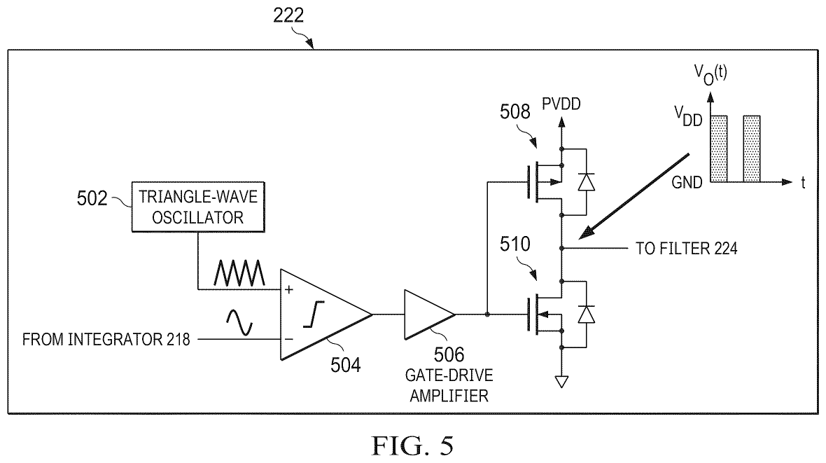

FIG. 5 illustrates an example circuit implementation of the positive voltage line of the power stage 222 of FIGS. 2 and 3. Because the output stage 222 is part of a fully differential system, a similar circuit can be implemented for the negative voltage line of the power stage 222. The power stage 222 of FIG. 5 includes an example triangle-wave oscillator 502, an example comparator 504, an example gate-drive amplifier 506, and example transistors 508, 510.

The triangle-wave oscillator 502 of FIG. 5 includes an output terminal. The output terminal of the triangle-wave oscillator 502 is coupled to the first input terminal of the comparator 504. The triangle-wave oscillator 502 generates a triangle wave that is output to the comparator 504.

The comparator 504 of FIG. 5 includes two input terminals and an output terminal. The first input terminal (e.g., the non-inverting terminal) of the comparator 504 is coupled to the output terminal of the triangle wave oscillator 502. The second input terminal (e.g., the inverting terminal) of the comparator 504 is coupled to the first output terminal of the integrator 218 and the first input of the integrator 218 (e.g., via a feedback capacitor). The output terminal of the comparator 504 is coupled to an input terminal of the gate-drive amplifier 506. The comparator 504 compares the triangle wave from the triangle-wave oscillator 502 to the analog voltage at the first output terminal of the integrator 218. If the triangle wave is higher than the analog voltage, the comparator 504 outputs a logic high voltage. Otherwise, the comparator 504 outputs a log low voltage. The comparator 504 outputs the output voltage to the gate-drive amplifier 506.

The gate-drive amplifier 506 of FIG. 5 includes an input terminal and an output terminal. The input terminal of the gate-drive amplifier 506 is coupled to the output terminal of the comparator 504. The output terminal of the gate-drive amplifier 506 is coupled to the control terminals of the transistors 508, 510. The gate-drive amplifier 506 (e.g., also referred to as a driver or driver circuitry) uses the output signal from the comparator 504 to drive the transistors 508, 510. For example, the gate-drive amplifier 506 can take the low voltage signal from the output to the comparator 504 and convert the to a higher voltage control signal that can push the control terminal of the transistors 508, 510 to properly control the transistors 508, 510.

The transistor 508 of FIG. 5 includes a control terminal, and two current terminals. The control terminal (e.g., gate terminal) of the transistor 508 is coupled to the output terminal of the gate-drive amplifier 506 and the control terminal of the transistor 510. The first current terminal (e.g., the source terminal) of the transistor 508 is coupled to a supply terminal (PVDD). The second current terminal (e.g., the drain terminal) of the transistor 508 is coupled to the first current terminal of the transistor 510 and to the filter 224 of FIG. 2 or 3. The transistor 508 is a p-channel metal oxide semiconductor field effect transistor (PMOS or P-channel MOSFET). However, a different type of transistor may be used to implement the transistor 508. The transistor 508 operates as a switch. For example, in situations where the voltage at the control terminal of the transistor 508 corresponds to a first voltage (e.g., a high voltage), the transistor 508 operates as a closed switch, thereby proving the PVDD voltage to the filter 224. In situations where the voltage at the control terminal of the transistor 508 corresponds to a second voltage (e.g., a low voltage), the transistor 508 operates as a closed switch, thereby blocking the PVDD voltage from reaching the filter 224.

The transistor 510 of FIG. 5 includes a control terminal, and two current terminals. The control terminal (e.g., gate terminal) of the transistor 510 is coupled to the output terminal of the gate-drive amplifier 506 and the control terminal of the transistor 508. The first current terminal (e.g., the drain terminal) of the transistor 510 is coupled to the second current terminal of the transistor 508 and to the filter 224 of FIG. 2 or 3. The second current terminal (e.g., the source terminal) of the transistor 510 is coupled to a common terminal (e.g., ground). The transistor 510 is an n-channel metal oxide semiconductor field effect transistor (NMOS or N-channel MOSFET). However, a different type of transistor may be used to implement the transistor 510. The transistor 510 operates as a switch. For example, in situations where the voltage at the control terminal of the transistor 510 corresponds to the second voltage (e.g., a low voltage), the transistor 510 operates as a closed switch, thereby proving the ground voltage (e.g., 0 V) to the filter 224. In situations where the voltage at the control terminal of the transistor 510 corresponds to the first voltage (e.g., a high voltage), the transistor 510 operates as a closed switch, thereby blocking the ground voltage from reaching the filter 224. The voltage at the output terminal of the output stage 222 is a pulse-width modulated signal that corresponds to the input audio signal, and is used to drive the speaker 108 of FIG. 1, 2, or 3, as further described above.

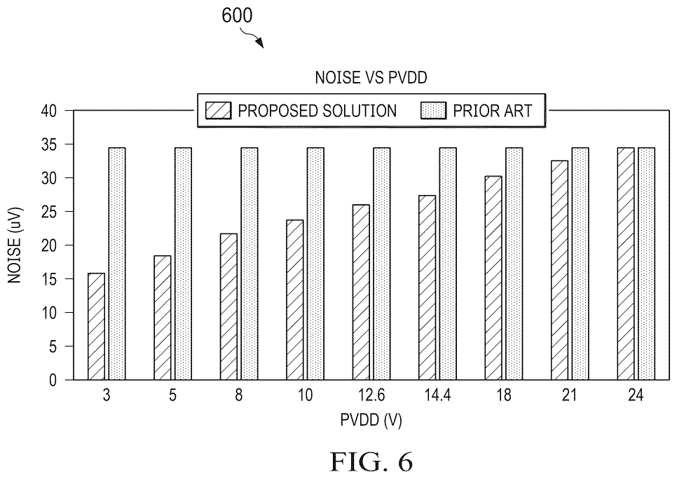

FIG. 6 illustrates an example graph 600 that illustrates a comparison of noise at different supply voltages of the output stage 222 using examples described herein versus techniques that do not utilize examples described herein. For example, as shown in the graph 600, the amount of noise associated with examples described herein for a 3 Volt PVDD results in 15 microvolts (uV) of noise, whereas techniques that do not utilizes examples described herein result in almost 35 uV of noise. Even at a 21 Volt PVDD, the noise is still around 3 uV less than techniques that do not utilize examples described herein.

One or more example manners of implementing the conversion circuitry 106 of FIG. 1 is illustrated in FIGS. 2-4. However, one or more of the elements, processes or devices illustrated in FIGS. 1-4 may be combined, divided, re-arranged, omitted, eliminated or implemented in any other way.

Further, the controller circuitry 230 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)) or field programmable logic device(s) (FPLD(s)).

When reading any of the apparatus or system claims of this patent to cover a purely software or firmware implementation, the controller circuitry 230 is hereby expressly defined to include a non-transitory computer readable storage device or storage disk such as a memory, a digital versatile disk (DVD), a compact disk (CD), a Blu-ray disk, etc., including the software or firmware. Further still, the controller circuitry 230 may include one or more elements, processes or devices in addition to, or instead of, those illustrated in FIGS. 2-3, or may include more than one of any or all of the illustrated elements, processes, and devices. As used herein, the phrase “in communication,” including variations thereof, encompasses direct communication or indirect communication through one or more intermediary components, and does not require direct physical (e.g., wired) communication or constant communication, but rather also includes selective communication at one or more of periodic intervals, scheduled intervals, aperiodic intervals, or one-time events.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

Descriptors “first,” “second,” “third,” etc. are used herein to identify multiple elements or components which may be referred to separately. Unless otherwise specified or known based on their context of use, such descriptors do not impute any meaning of priority, physical order, or arrangement in a list, or ordering in time but are merely used as labels for referring to multiple elements or components separately for ease of understanding the described examples. In some examples, the descriptor “first” may be used to refer to an element in the detailed description, while the same element may be referred to in a claim with a different descriptor such as “second” or “third.” In such instances, such descriptors are used merely for ease of referencing multiple elements or components.

In the description and in the claims, the terms “including” and “having,” and variants thereof are to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The terms “couple,” “coupled,” “couples,” and variants thereof, as used herein, may cover connections, communications, or signal paths that enable a functional relationship consistent with this description. For example, if device A generates a signal to control device B to perform an action, if a first example device A is coupled to device B, or if a second example device A is coupled to device B through intervening component C if intervening component C does not substantially alter the functional relationship between device A and device B, such that device B is controlled by device A via the control signal generated by device A. Moreover, the terms “couple,” “coupled”, “couples”, or variants thereof, includes an indirect or direct electrical or mechanical connection.

A device that is “configured to” perform a task or function may be configured (e.g., at least one of programmed or hardwired) at a time of manufacturing by a manufacturer to perform the function or may be configurable (or re-configurable) by a user after manufacturing to perform the function or other additional or alternative functions. The configuring may be through at least one firmware or software programming of the device, through a construction or layout of hardware components and interconnections of the device, or a combination thereof.

Although not all separately labeled in the FIGS. 1-4, components or elements of systems and circuits illustrated therein have one or more conductors or terminus that allow signals into or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on particular circuitry or system topology, there may be more or fewer terminals and nodes. However, in some instances, “terminal,” “node,” “interconnect,” “pad,” and “pin” may be used interchangeably.

The term “or” as used, for example, in a form such as A, B, or C refers to any combination or subset of A, B, C such as (1) A alone, (2) B alone, (3) C alone, (4) A with B, (5) A with C, (6) B with C, or (7) A with B and with C.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Example methods, apparatus, systems, and articles of manufacture to correct non-linearity in transmitters are described herein. Further examples and combinations thereof include the following: Example 1 includes an apparatus comprising first resistor circuitry having a terminal, a capacitor having a first terminal and a second terminal, an integrator having an input terminal and an output terminal, the input terminal of the integrator coupled to the terminal of the first resistor circuitry and the first terminal of the capacitor, and the output terminal of the integrator coupled to the second terminal of the capacitor, an output stage having an input terminal and an output terminal, the input terminal of the output stage coupled to the output terminal of the integrator, second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator, and third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal.

Example 2 includes the apparatus of example 1, further including a digital-to-analog converter including an output terminal wherein the first resistor circuitry has a second terminal coupled to the output terminal of the digital-to-analog converter.

Example 3 includes the apparatus of example 1, further including a filter, the filter having an input and an output, wherein the input of the filter is coupled to the output terminal of the output stage is the output of the filter is coupled to a speaker.

Example 4 includes the apparatus of example 1, wherein the first resistor circuitry is variable resistor circuitry having a resistance that varies based on an input audio signal.

Example 5 includes the apparatus of example 1, wherein the second resistor circuitry is static resistor circuitry.

Example 6 includes the apparatus of example 1, further including gain circuitry having an output terminal, wherein the first resistor circuitry has a control terminal coupled to the output terminal of the gain circuitry.

Example 7 includes the apparatus of example 6, wherein the gain circuitry adjusts resistance of the first resistor circuitry based on an input audio signal.

Example 8 includes an apparatus comprising a capacitor having a first terminal and a second terminal, resistor circuitry having a first terminal and a second terminal, an integrator having an input terminal and an output terminal, the input terminal of the integrator coupled to the first terminal of the capacitor and the output terminal of the integrator coupled to the second terminal of the capacitor, an output stage having an input terminal and an output terminal, the input terminal of the output stage coupled to the output terminal of the integrator, the output terminal of the output stage coupled to the first terminal of the resistor circuitry, a variable resistor having a first terminal, a second terminal, and a control terminal, the first terminal of the variable resistor coupled to the second terminal of the resistor circuitry and the input terminal of the integrator, the second terminal of the variable resistor coupled to a common terminal; control circuitry including a first terminal and a second terminal, an analog-to-digital converter having an input terminal and an output terminal, and regulation circuitry having a first input terminal, a second input terminal, a third input terminal, and an output terminal, the first input terminal of the regulation circuitry coupled to the output terminal of the analog-to-digital converter, the second input terminal of the regulation circuitry coupled to the first terminal of the control circuitry, and the third input terminal of the regulation circuitry coupled to the second terminal of the control circuitry, the output terminal of the regulation circuitry coupled to the control terminal of the variable resistor.

Example 9 includes the apparatus of example 8, wherein the regulation circuitry includes a lookup table.

Example 10 includes the apparatus of example 8, wherein the input terminal of the analog-to-digital converter is a first input terminal, the analog-to-digital converter further having a second input terminal, the first input terminal of the analog-to-digital converter coupled to a supply voltage terminal of the output stage, and the second input terminal of the analog-to-digital converter coupled to a common mode terminal, the common mode terminal coupled to the input terminal of the integrator.

Example 11 includes the apparatus of example 10, further including a resistor having a first terminal and a second terminal, the first terminal of the resistor coupled to the common mode terminal and the second terminal of the resistor coupled to the input terminal of the integrator.

Example 12 includes the apparatus of example 8, wherein the regulation circuitry is configured to control a resistance of the variable resistor based on at least one of a gain of the apparatus, a common mode input voltage, a modulation duty cycle, and a supply voltage of the output stage.

Example 13 includes the apparatus of example 8, further including a switch having a first terminal and a second terminal, the first terminal of the switch coupled to the first terminal of the integrator and the first terminal of the resistor circuitry, the second terminal of the switch coupled to the first terminal of the variable resistor.

Example 14 includes the apparatus of example 8, wherein the resistance circuitry is feedback resistance circuitry, further including a digital-to-analog converter, and input resistance circuitry having a first terminal and a second terminal, the first terminal of the input resistance circuitry coupled to the digital-to-analog converter, the second terminal of the input resistance circuitry coupled to the input terminal of the integrator, the second terminal of the feedback resistance circuitry, and the first terminal of the variable resistor.

Example 15 includes the apparatus of example 8, further including a speaker including an input terminal, and a filter including an input terminal and an output terminal, the input terminal of the filter coupled to the output terminal of the output stage, the output terminal of the filter coupled to the input terminal of the speaker.

Example 16 includes a system comprising a processing unit configured to output an audio signal, a digital-to-analog converter configured to convert the audio signal into an analog audio signal, amplifier circuitry to convert the analog audio signal into a pulse width modulated audio signal, the amplifier circuitry including a capacitor having a first terminal and a second terminal, first resistor circuitry having a terminal, an integrator having an input terminal and an output terminal, the input terminal of the integrator coupled to the terminal of the first resistor circuitry and the first terminal of the capacitor, and the output terminal of the integrator coupled to the second terminal of the capacitor, an output stage having an input terminal and an output terminal, the input terminal of the output stage coupled to the output terminal of the integrator, second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator, and third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal, and a speaker configured to output audio, the speaker having an input terminal, the input terminal of the speaker coupled to the output terminal of the output stage.

Example 17 includes the system of example 16, wherein the terminal of the first resistor circuitry is a first terminal, wherein the first resistor circuitry has a second terminal, and the digital-to-analog converter has an output terminal, the output terminal of the digital-to-analog converter coupled to the second terminal of the first resistor circuitry.

Example 18 includes the system of example 16, further including a filter having an input terminal and an output terminal, the input terminal of the filter coupled to the output terminal of the output stage, the output terminal of the filter coupled to the input terminal of the speaker.

Example 19 includes the system of example 16, wherein the output stage is configured to convert the analog audio signal into the pulse width modulated audio signal.

Example 20 includes the system of example 19, wherein the speaker is configured to output the audio based on the pulse width modulated audio signal

From the foregoing, it will be appreciated that example systems, apparatus, articles of manufacture, and methods have been described that regulates an amplifier. Described systems, apparatus, articles of manufacture, and methods improve the efficiency of using amplifiers by reducing the noise and increasing the CMRR across a wide range of output supply voltage, hybrid modulation duty cycle, input common mode voltage, and gain. Also, examples described herein are area and power efficient. Described systems, apparatus, articles of manufacture, and methods are accordingly directed to one or more improvement(s) in the operation of a machine such as a computer or other electronic device.

Modifications are possible in the described examples, and other examples are possible, within the scope of the claims.

What is claimed is:

1. An apparatus comprising:
first resistor circuitry having a terminal;
a capacitor having a first terminal and a second terminal;
an integrator having an input terminal and an output terminal, the input terminal of the integrator coupled to the terminal of the first resistor circuitry and the first terminal of the capacitor, and the output terminal of the integrator coupled to the second terminal of the capacitor;
an output stage having an input terminal and an output terminal, the input terminal of the output stage coupled to the output terminal of the integrator;
second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator; and
third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal.

2. The apparatus of claim 1, further including a digital-to-analog converter including an output terminal wherein the first resistor circuitry has a second terminal coupled to the output terminal of the digital-to-analog converter.

3. The apparatus of claim 1, further including a filter, the filter having an input and an output, wherein the input of the filter is coupled to the output terminal of the output stage is the output of the filter is coupled to a speaker.

4. The apparatus of claim 1, wherein the first resistor circuitry is variable resistor circuitry having a resistance that varies based on an input audio signal.

5. The apparatus of claim 1, wherein the second resistor circuitry is static resistor circuitry.

6. The apparatus of claim 1, further including gain circuitry having an output terminal, wherein the first resistor circuitry has a control terminal coupled to the output terminal of the gain circuitry.

7. The apparatus of claim 6, wherein the gain circuitry adjusts resistance of the first resistor circuitry based on an input audio signal.

8. An apparatus comprising:
a capacitor having a first terminal and a second terminal;
resistor circuitry having a first terminal and a second terminal;
an integrator having an input terminal and an output terminal, the input terminal of the integrator coupled to the first terminal of the capacitor and the output terminal of the integrator coupled to the second terminal of the capacitor;
an output stage having an input terminal and an output terminal, the input terminal of the output stage coupled to the output terminal of the integrator, the output terminal of the output stage coupled to the first terminal of the resistor circuitry;
a variable resistor having a first terminal, a second terminal, and a control terminal, the first terminal of the variable resistor coupled to the second terminal of the resistor circuitry and the input terminal of the integrator, the second terminal of the variable resistor coupled to a common terminal;
control circuitry including a first terminal and a second terminal;
an analog-to-digital converter having an input terminal and an output terminal; and
regulation circuitry having a first input terminal, a second input terminal, a third input terminal, and an output terminal, the first input terminal of the regulation circuitry coupled to the output terminal of the analog-to-digital converter, the second input terminal of the regulation circuitry coupled to the first terminal of the control circuitry, and the third input terminal of the regulation circuitry coupled to the second terminal of the control circuitry, the output terminal of the regulation circuitry coupled to the control terminal of the variable resistor.

9. The apparatus of claim 8, wherein the regulation circuitry includes a lookup table.

10. The apparatus of claim 8, wherein the input terminal of the analog-to-digital converter is a first input terminal, the analog-to-digital converter further having a second input terminal, the first input terminal of the analog-to-digital converter coupled to a supply voltage terminal of the output stage, and the second input terminal of the analog-to-digital converter coupled to a common mode terminal, the common mode terminal coupled to the input terminal of the integrator.

11. The apparatus of claim 10, further including a resistor having a first terminal and a second terminal, the first terminal of the resistor coupled to the common mode terminal and the second terminal of the resistor coupled to the input terminal of the integrator.

12. The apparatus of claim 8, wherein the regulation circuitry is configured to control a resistance of the variable resistor based on at least one of a gain of the apparatus, a common mode input voltage, a modulation duty cycle, and a supply voltage of the output stage.

13. The apparatus of claim 8, further including a switch having a first terminal and a second terminal, the first terminal of the switch coupled to the first terminal of the integrator and the first terminal of the resistor circuitry, the second terminal of the switch coupled to the first terminal of the variable resistor.

14. The apparatus of claim 8, wherein the resistance circuitry is feedback resistance circuitry, further including:
a digital-to-analog converter; and
input resistance circuitry having a first terminal and a second terminal, the first terminal of the input resistance circuitry coupled to the digital-to-analog converter, the second terminal of the input resistance circuitry coupled to the input terminal of the integrator, the second terminal of the feedback resistance circuitry, and the first terminal of the variable resistor.

15. The apparatus of claim 8, further including:
a speaker including an input terminal; and
a filter including an input terminal and an output terminal, the input terminal of the filter coupled to the output terminal of the output stage, the output terminal of the filter coupled to the input terminal of the speaker.

16. A system comprising:
a processing unit configured to output an audio signal;
a digital-to-analog converter configured to convert the audio signal into an analog audio signal;
amplifier circuitry to convert the analog audio signal into a pulse width modulated audio signal, the amplifier circuitry including:
a capacitor having a first terminal and a second terminal;
first resistor circuitry having a terminal;
an integrator having an input terminal and an output terminal, the input terminal of the integrator coupled to the terminal of the first resistor circuitry and the first terminal of the capacitor, and the output terminal of the integrator coupled to the second terminal of the capacitor;
an output stage having an input terminal and an output terminal, the input terminal of the output stage coupled to the output terminal of the integrator;
second resistor circuitry having a first terminal and a second terminal, the first terminal of the second resistor circuitry coupled to the output terminal of the output stage, the second terminal of the second resistor circuitry coupled to the terminal of the first resistor circuitry and the input terminal of the integrator; and
third resistor circuitry having a first terminal and a second terminal, the first terminal coupled to the terminal of the first resistor circuitry, the second terminal of the second resistor circuitry, and the input terminal of the integrator, the second terminal of the third resistor circuitry coupled to a common terminal; and
a speaker configured to output audio, the speaker having an input terminal, the input terminal of the speaker coupled to the output terminal of the output stage.

17. The system of claim 16, wherein the terminal of the first resistor circuitry is a first terminal, wherein:
the first resistor circuitry has a second terminal; and
the digital-to-analog converter has an output terminal, the output terminal of the digital-to-analog converter coupled to the second terminal of the first resistor circuitry.

18. The system of claim 16, further including a filter having an input terminal and an output terminal, the input terminal of the filter coupled to the output terminal of the output stage, the output terminal of the filter coupled to the input terminal of the speaker.

19. The system of claim 16, wherein the output stage is configured to convert the analog audio signal into the pulse width modulated audio signal.

20. The system of claim 19, wherein the speaker is configured to output the audio based on the pulse width modulated audio signal.
